(19) United States
(12) Patent Application Publication
(10) Pub. No.: US 2022/0027153 A1
(43) Pub. Date: Jan. 27, 2022

(54) DIGITAL SIGNAL PROCESS DEVICE AND METHOD FOR ELECTRIC ENERGY METERING CHIP

(71) Applicant: HANGZHOU VANGO TECHNOLOGIES,INC., Hangzhou (CN)

(72) Inventors: Xiaohui XIAO, Hangzhou (CN); Jie CAO, Hangzhou (CN); Zhaosheng DU, Hangzhou (CN); Nick Nianxiong Tan, Hangzhou (CN)

(73) Assignee: HANGZHOU VANGO TECHNOLOGIES,INC., Hangzhou (CN)

(21) Appl. No.: 17/494,848

(22) Filed: Oct. 6, 2021

(30) Foreign Application Priority Data
Jan. 4, 2021 (CN) 202110003900.1

(51) Int. Cl. G06F 9/30; G06F 9/54

(52) U.S. Cl. CPC G06F 9/3001; G06F 9/30098; G06F 9/545; G06F 9/30196

(57) ABSTRACT

A digital signal process device includes a first kernel module, configured for generating a corresponding control signal according to a DSP instruction code in a first read-only memory; a second kernel module, configured for generating a corresponding control signal according to a DSP instruction code in a second read-only memory; an arbitration module, configured for receiving a control signal corresponding to a memory access instruction and/or an arithmetic instruction sent by the first kernel module and the second kernel module, and screening out a control signal corresponding to a target memory access instruction and/or a target arithmetic instruction according to a preset priority; a data storage module, configured for receiving the control signal corresponding to the target memory access instruction sent by the arbitration module; and an arithmetic logic unit, configured for receiving the control signal corresponding to the target arithmetic instruction sent by the arbitration module.

### CROSS-REFERENCE TO RELATED APPLICATION

This application claims the priority benefit of China application serial no. 202110003900.1 filed on Jan. 4, 2021. The entirety of the above-mentioned patent application is hereby incorporated by reference herein and made a part of this specification.

### BACKGROUND

### Technical Field

The present invention relates to the field of digital signal process, and particularly, to a digital signal process device and method for an electric energy metering chip.

### Description of Related Art

At present, with the development of smart power grids, a new generation of single-phase smart IOT (Internet of Things) electric energy meter not only needs to provide traditional measurement and metering data, such as active power, reactive power, root-mean-square value, apparent power, active and reactive energy, or the like, of fundamental waves/full-waves, but also needs to provide relevant data, including electric energy quality and electric meter running statuses, so as to help make better power distribution decisions, such as measuring harmonics through harmonic analysis and detecting a distortion rate of power grid signals through harmonic analysis, providing reference for harmonic control of the power grids, and improving the electric energy quality. For another example, abnormal electric meter running statuses, such as overheating of a terminal block, drastic changes in the temperature of the terminal block, unbalanced temperature of the terminal block, or the like, are detected through measuring the temperature of the terminal block, so as to generate an alarm or make a trip decision in time. Faced with the implementation of multiple functions, it is necessary to upgrade an electric energy metering chip to meet the application requirements of the new generation of smart IoT electric energy meter. In view of implementation costs and certain flexibility, the electric energy metering chip is usually implemented in an ASIC (Application Specific Integrated Circuit) mode by using a dedicated DSP (Digital Signal Process) as an operation kernel. In the related art, when an operational ability of the DSP can no longer meet new requirements, the operational ability of the DSP is improved by doubling a clock frequency of a system, but the increased clock frequency of the system increases power consumption. Moreover, a built-in PLL needs to be added or a crystal oscillator with a higher frequency needs to be replaced to improve the frequency, which increases the cost. In the related art, the operation capability of the DSP is also improved by adding one DSP kernel, but other configurations and internal control logics of the DSP will be newly added while adding one DSP kernel, which increases the cost and complexity. Therefore, how to improve the operational ability of the DSP on the basis of keeping low power consumption and low cost is an urgent problem to be solved at present.

### SUMMARY

In light of this, the present invention aims at providing a digital signal process device and method for an electric energy metering chip, which can improve an operational ability of a DSP while ensuring low power consumption. The specific solutions of the present invention are as follows.

According to a first aspect, the present application discloses a digital signal process device for an electric energy metering chip, including:

a first kernel module, configured for generating a corresponding control signal according to a DSP instruction code in a first read-only memory;

a second kernel module, configured for generating a corresponding control signal according to a DSP instruction code in a second read-only memory; wherein the DSP instruction includes an arithmetic instruction, a memory access instruction, a jump instruction and a no-operation instruction;

an arbitration module respectively connected with the first kernel module and the second kernel module, configured for receiving a control signal corresponding to a memory access instruction and/or an arithmetic instruction sent by the first kernel module and the second kernel module, and screening out a control signal corresponding to a target memory access instruction and/or a target arithmetic instruction according to a preset priority;

a data storage module connected with the arbitration module, configured for receiving and executing the control signal corresponding to the target memory access instruction sent by the arbitration module; and

an arithmetic logic unit connected with the arbitration module, configured for receiving and executing the control signal corresponding to the target arithmetic instruction sent by the arbitration module.

Optionally, the first kernel module includes:

a first program counter, configured for generating a memory address corresponding to the DSP instruction;

the first read-only memory connected with the first program counter, configured for storing the DSP instruction code, and determining the corresponding DSP instruction according to the memory address and sending the corresponding DSP instruction to a first instruction decoder;

the first instruction decoder connected with the first read-only memory, configured for decoding the DSP instruction to obtain the corresponding control signal, and sending, to the arbitration module, the control signal corresponding to the arithmetic instruction and the control signal corresponding to the memory access instruction obtained by decoding;

a first address mapping module connected with the first instruction decoder, configured for determining a physical address of a virtual address remapped to a data memory according to the control signal; and

a first general purpose register connected with the first instruction decoder, configured for storing data information acquired from the data memory after the memory access instruction is executed and storing result information acquired from the arithmetic logic unit after the arithmetic instruction is executed;

wherein the first program counter is further connected with the first instruction decoder and the first general purpose register respectively, and the first program counter is further configured for receiving a control signal corresponding to a direct jump instruction, a control signal corresponding to a no-operation instruction and a control signal corresponding to a conditional jump instruction sent by the first instruction decoder, and executing the control signal corresponding to the conditional jump instruction according to a jump condition parameter in the first general purpose register.

Optionally, the second kernel module includes:

a second program counter, configured for generating a memory address corresponding to the DSP instruction;

the second read-only memory connected with the second program counter, configured for storing the DSP instruction code, and determining the corresponding DSP instruction according to the memory address and sending the corresponding DSP instruction to a second instruction decoder;

the second instruction decoder connected with the second read-only memory, configured for decoding the DSP instruction to obtain the corresponding control signal, and sending, to the arbitration module, the control signal corresponding to the arithmetic instruction and the control signal corresponding to the memory access instruction obtained by decoding;

a second address mapping module connected with the second instruction decoder, configured for determining a physical address of a virtual address remapped to a data memory according to the control signal; and

a second general purpose register connected with the second instruction decoder, configured for storing data information acquired from the data memory after the memory access instruction is executed and storing result information acquired from the arithmetic logic unit after the arithmetic instruction is executed;

wherein the second program counter is further connected with the second instruction decoder and the second general purpose register respectively, and the second program counter is further configured for receiving a control signal corresponding to a direct jump instruction, a control signal corresponding to a no-operation instruction and a control signal corresponding to a conditional jump instruction sent by the second instruction decoder, and executing the control signal corresponding to the conditional jump instruction according to a jump condition parameter in the second general purpose register.

Optionally, the data storage module includes:

the data memory, configured for storing data information; and

a memory management unit connected with the arbitration module and the data memory, configured for querying corresponding data information in the data memory according to the physical addresses determined by the first address mapping module and the second address mapping module.

Optionally, the data memory includes:

a random access memory, configured for storing an intermediate variable, a preset parameter and a metering result; and

a register block, configured for storing real time data corresponding to a target hardware device.

Optionally, the arbitration module includes a memory management unit arbitrator and an arithmetic logic unit arbitrator, wherein:

the memory management unit arbitrator is configured for receiving the control signal corresponding to the memory access instruction sent by the first kernel module and the second kernel module, and screening out the control signal corresponding to the target memory access instruction according to the preset priority, and then sending the control signal corresponding to the target memory access instruction to the memory management unit; and

the arithmetic logic unit arbitrator is configured for receiving the control signal corresponding to the arithmetic instruction sent by the first kernel module and the second kernel module, and screening out the control signal corresponding to the target arithmetic instruction according to the preset priority, and then sending the control signal corresponding to the target arithmetic instruction to the arithmetic logic unit.

Optionally, the memory management unit arbitrator is further configured for, when receiving the control signals corresponding to the memory access instruction sent by the first kernel module and the second kernel module simultaneously, lowering a data valid signal of the second kernel module to stop running the second program counter, and raising the data valid signal after the current memory access instruction is completely executed; and

the arithmetic logic unit arbitrator is further configured for, when receiving the control signals corresponding to the arithmetic instruction sent by the first kernel module and the second kernel module simultaneously, lowering the data valid signal of the second kernel module to stop running the second program counter, and raising the data valid signal after the current arithmetic instruction is completely executed.

According to a second aspect, the present application discloses a digital signal process method for an electric energy metering chip, including:

generating a corresponding control signal according to a DSP instruction code in a first read-only memory;

generating a corresponding control signal according to a DSP instruction code in a second read-only memory; wherein the DSP instruction includes an arithmetic instruction, a memory access instruction, a jump instruction and a no-operation instruction;

receiving, by an arbitration module, a control signal corresponding to a memory access instruction and/or an arithmetic instruction sent by the first kernel module and the second kernel module, and screening out a control signal corresponding to a target memory access instruction and/or a target arithmetic instruction according to a preset priority;

receiving and executing, by a data storage module, the control signal corresponding to the target memory access instruction sent by the arbitration module; and

receiving and executing, by an arithmetic logic unit, the control signal corresponding to the target arithmetic instruction sent by the arbitration module.

In this application, the corresponding control signal is generated by the first kernel module according to the DSP instruction code in the first read-only memory, and the corresponding control signal is generated by the second kernel module according to the DSP instruction code in the second read-only memory, wherein the DSP instruction includes the arithmetic instruction, the memory access instruction, the jump instruction and the no-operation instruction; then the arbitration module respectively connected with the first kernel module and the second kernel module is used to receive the control signal corresponding to the memory access instruction and/or the arithmetic instruction sent by the first kernel module and the second kernel module, and screen out the control signal corresponding to the target memory access instruction and/or the target arithmetic instruction according to the preset priority; and then, the control signal corresponding to the target memory access instruction is received and executed by the data storage module, and the control signal corresponding to the target arithmetic instruction is received and executed by the arithmetic logic unit. It can be seen that the operational ability of the DSP is improved by newly adding one kernel. Meanwhile, the product cost is reduced since the first kernel module and the second kernel module share the data storage module and the arithmetic logic unit, and the running power consumption is reduced without increasing the clock frequency of the system.

### BRIEF DESCRIPTION OF THE DRAWINGS

In order to illustrate the technical solutions in the embodiments of the present invention or in the related art more clearly, the drawings used in the description of the embodiments or the prior art will be briefly described below. Obviously, the drawings in the following description are merely some embodiments of the present invention. For those of ordinary skills in the art, other drawings may also be obtained based on these drawings provided without going through any creative work.

FIG. 1 is a schematic structural diagram of a digital signal process device for an electric energy metering chip provided by the present application;

FIG. 2 is a schematic diagram of instruction execution of a first kernel module and a second kernel module provided by the present application;

FIG. 3 is a schematic structural diagram of a specific digital signal process device for an electric energy metering chip provided by the present application;

FIG. 4 is a schematic structural diagram of a specific digital signal process device for an electric energy metering chip provided by the present application;

FIG. 5 is a schematic diagram of a data storage architecture provided by the present application; and

FIG. 6 is a flow chart of a digital signal process method for an electric energy metering chip provided by the present application.

### DETAILED DESCRIPTION

In the related art, an operational ability of a DSP is improved by doubling a clock frequency of a system, but the increased clock frequency of the system increases power consumption. In the related art, the operation capability of the DSP is also improved by adding one DSP kernel, but other configurations and internal control logics of the DSP will be newly added while adding one DSP kernel, which increases the cost and complexity. In order to overcome the above technical problems, the present application proposes a digital signal process device for an electric energy metering chip, which can improve the operational ability of the

DSP while implementing low power operation of the system.

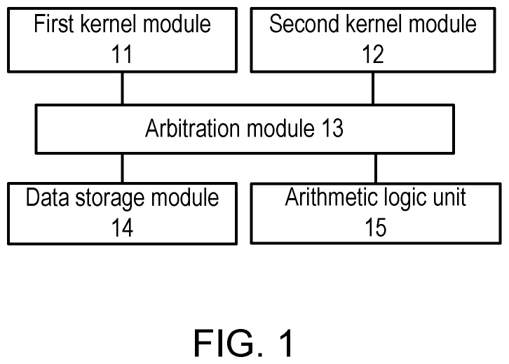

The embodiments of the present application disclose a digital signal process device for an electric energy metering chip. As shown in FIG. 1, the device includes:

a first kernel module 11 for generating a corresponding control signal according to a DSP instruction code in a first read-only memory.

In this embodiment, the first kernel module 11 generates the corresponding control signal by reading the DSP instruction code in the first read-only memory thereof. It can be understood that the first kernel module 11 reads the DSP instruction code in the first read-only memory thereof through an internal instruction decoder thereof, and obtains various control information signals to control different modules or units to perform corresponding operations, so as to complete the corresponding DSP instruction.

a first kernel module 11, configured for generating a corresponding control signal according to a DSP instruction code in a second read-only memory; wherein the DSP instruction includes an arithmetic instruction, a memory access instruction, a jump instruction and a no-operation instruction;

In this embodiment, the second kernel module 12 generates the corresponding DSP instruction by reading the DSP instruction code in the second read-only memory thereof. Similarly, the second kernel module 12 reads the DSP instruction code in the second read-only memory thereof through an internal instruction decoder thereof, and obtains various control information signals to control different modules or units to perform corresponding operations, so as to complete the corresponding DSP instruction. It can be understood that both the first kernel module 11 and the second kernel module 12 contain their own read-only memories. A user may write a task into the first read-only memory or the second read-only memory, and then the first kernel module 11 and the second kernel module 12 control to complete the corresponding instruction task. The DSP instruction stored in the first kernel module 11 and the second kernel module 12 includes but is not limited to an arithmetic instruction (ALU), a memory access instruction (MMU), a jump instruction (JMP) and a no-operation instruction (NOP).

An arbitration module 13 respectively connected with the first kernel module 11 and the second kernel module 12, configured for receiving a control signal corresponding to the memory access instruction and/or the arithmetic instruction sent by the first kernel module 11 and the second kernel module 12, and screening out a control signal corresponding to a target memory access instruction and/or a target arithmetic instruction according to a preset priority.

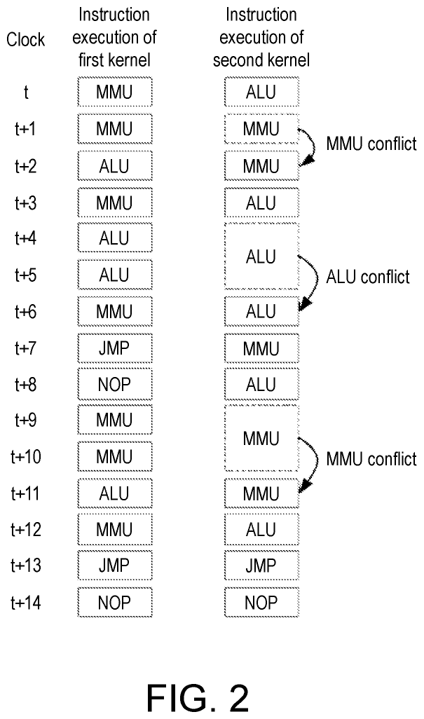

In this embodiment, the arbitration module, after receiving the control signal corresponding to the memory access instruction and/or the control signal corresponding to the arithmetic instruction sent by the first kernel module 11 and the second kernel module 12 above, may screen out the control signal corresponding to the target memory access instruction and/or the control signal corresponding to the target arithmetic instruction according to the preset priority. The above priority is a preset priority for the kernel modules. It can be understood that multiple memory access instructions cannot be executed at the same time, but only one memory access instruction can be executed; and similarly, multiple arithmetic instructions cannot be executed at the same time, but only one arithmetic instruction can be executed. Therefore, when the control signals corresponding to the memory access instructions sent by the first kernel module 11 and the second kernel module 12 are received at the same time, the control signal corresponding to the memory access instruction sent by the kernel module with a higher priority may be selected as the control signal of the above target memory access instruction according to the preset priority. Similarly, when the control signals corresponding to the arithmetic instructions sent by the first kernel module 11 and the second kernel module 12 are received at the same time, the control signal corresponding to the arithmetic instruction sent by the kernel module with a higher priority may be selected as the control signal of the above target arithmetic instruction according to the preset priority. However, the memory access instruction, the arithmetic instruction and other types of instructions may be executed at the same time. In this way, the user may write tasks into the first read-only memory and the second read-only memory in groups for the first kernel module 11 and the second kernel module 12 to execute. For example, a priority of the first kernel module 11 is set to be higher than that of the second kernel module 12, and most tasks are stored in the first read-only memory for the first kernel module 11 to execute, while a small number of tasks are stored in the second read-only memory for the second kernel module 12 to execute. In this way, the first kernel module 11 can work without pause, making full use of 1,024 clock cycles, and the remaining tasks are handed over to the second kernel module 12 to execute. To be specific, instruction execution flows of the first kernel module 11 and the second kernel module 12 may be as shown in FIG. 2. When the first kernel module 11 and the second kernel module 12 have a memory access instruction conflict or an arithmetic instruction conflict, the second kernel module 12 is paused. After the current memory access instruction or arithmetic instruction of the first kernel module 11 is completed, the second kernel module 12 is restarted.

A data storage module 14 connected with the arbitration module 13, configured for receiving and executing the control signal corresponding to the target memory access instruction sent by the arbitration module.

In this embodiment, the data storage module 14, after receiving the control signal corresponding to the target memory access instruction sent by the arbitration module 13, feeds back corresponding data information according to the control signal to implement the target memory access instruction.

An arithmetic logic unit 15 connected with the arbitration module 13, configured for receiving and executing the control signal corresponding to the target arithmetic instruction sent by the arbitration module, so as to implement the target arithmetic instruction.

In this embodiment, the ALU (Arithmetic Logic Unit) 15, after receiving the control signal corresponding to the target arithmetic instruction sent by the arbitration module 13, performs logical operation according to the control signal and feeds back a corresponding operation result. It can be understood that a time-domain integral algorithm is employed as an electric energy metering algorithm, including electric signal generating and electric energy data metering. The electric signal generating is mainly to filter the results sampled by ADC to obtain a signal for electric energy data metering, which are mainly composed of various filters, including a CIC filter, an HBF filter, a Hilbert filter and the like. Operations such as addition and subtraction, multiplication, square root and averaging may be performed during electric energy data metering. Meanwhile, a multi-rate operating system is employed as a metering system. To control the rate, instructions need to be compared. Therefore, the arithmetic instructions included in the arithmetic logic unit 15 include but are not limited to ADD (Addition), SUB (Subtraction), SHFT (Shifting), MULT (Multiplication), SQRT (Square Root), and CND (Comparison).

It can be seen from the above that in this embodiment, compared with the prior art, by adding one kernel module, the operational ability of the DSP can be improved without increasing a clock frequency, and the running power consumption can be reduced. Moreover, the cost can be reduced since the two kernels share the data storage module and the arithmetic logic unit. Because the first kernel module and the second kernel module share the same data storage module and the same arithmetic logic unit, an area cost is reduced compared with a traditional dual-kernel structure. Meanwhile, the second kernel module with a lower priority also has a certain operational ability, and in the DSP program, the memory access instruction and the arithmetic instruction are usually executed alternately, so the data storage module and the arithmetic logic unit may not be occupied for a long term. Only when the first kernel module and the second kernel module both execute memory access instructions, or when the first kernel module and the second kernel module both execute arithmetic instructions, the second kernel module will stop running. However, since the data storage module and the arithmetic logic unit will not be occupied for a long time, the second kernel module will continue to execute again soon. Moreover, other types of instruction combinations can run in parallel. In this way, an operational ability of a digital signal processor in the electric energy metering chip is improved with low power consumption and low cost, so as to complete more metering algorithms and meet the requirements of the application specifications of the new generation single-phase smart electric meters, such as temperature measuring of a terminal block, harmonic analysis and other functions.

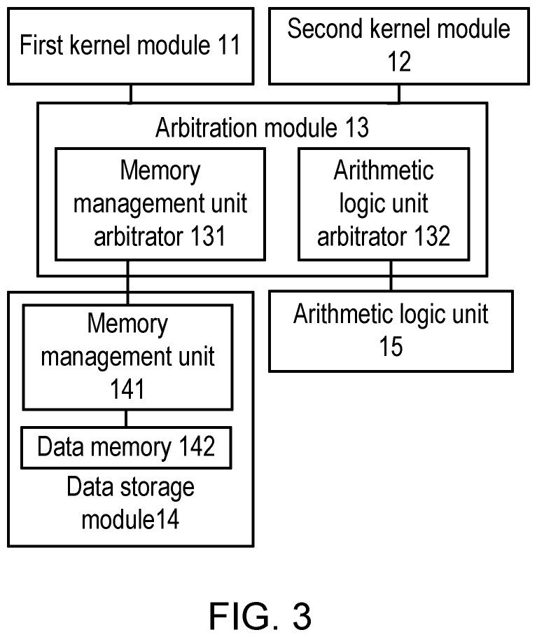

The embodiments of the present application disclose a specific digital signal process device for an electric energy metering chip. As shown in FIG. 3, the device includes:

a first kernel module 11 for generating a corresponding control signal according to a DSP instruction code in a first read-only memory.

In this embodiment, the first kernel module 11 may include: a first program counter, configured for generating a memory address corresponding to the DSP instruction; the first read-only memory connected with the first program counter, configured for storing the DSP instruction code, and determining the corresponding DSP instruction according to the memory address and sending the corresponding DSP instruction to a first instruction decoder; the first instruction decoder connected with the first read-only memory, configured for decoding the DSP instruction to obtain the corresponding control signal, and sending, to the arbitration module, the control signal corresponding to the arithmetic instruction and the control signal corresponding to the memory access instruction obtained by decoding; a first address mapping module connected with the first instruction decoder, configured for determining a physical address of a virtual address remapped to the data memory according to the control signal; and a first general purpose register connected with the first instruction decoder, configured for storing data information acquired from the data memory after the memory access instruction is executed and storing result information acquired from the arithmetic logic unit after the arithmetic instruction is executed; wherein the first program counter is further connected with the first instruction decoder and the first general purpose register respectively, and is the first program counter further configured for receiving a control signal corresponding to a direct jump instruction, a control signal corresponding to a no-operation instruction and a control signal corresponding to a conditional jump instruction sent by the first instruction decoder, and executing the control signal corresponding to the conditional jump instruction according to a jump condition parameter in the first general purpose register.

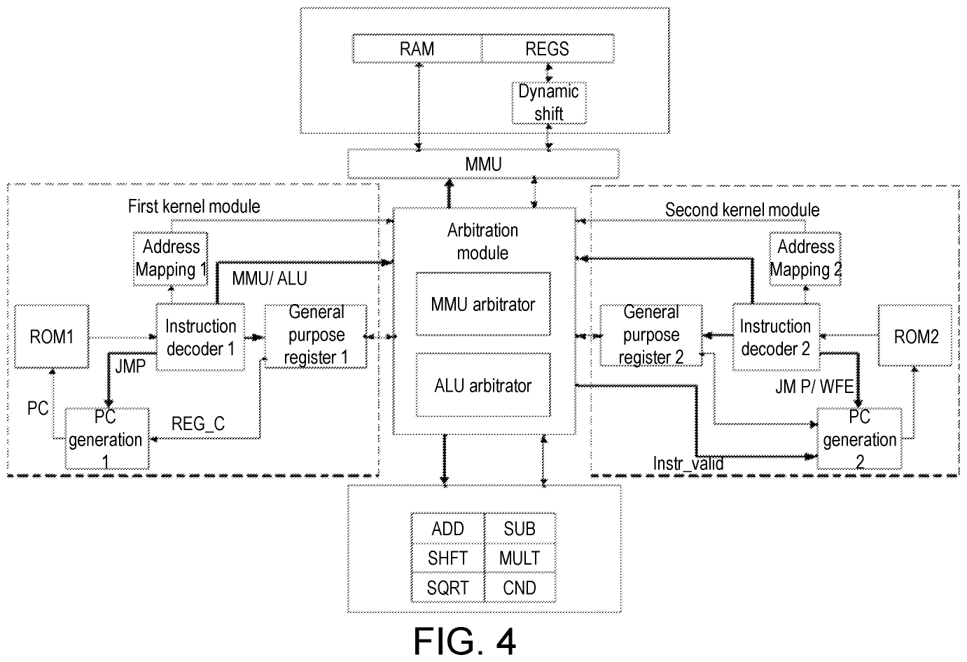

It can be understood that, for example, as shown in FIG. 4, the first PC (Program Counter) in the first kernel module 11 generates 1, generates the memory address (i.e., a pointer) corresponding to the DSP instruction, and sends the memory address to the first read-only memory ROM1. The first read-only memory determines the corresponding DSP instruction according to the received memory address and sends the corresponding DSP instruction to the first instruction decoder. The first instruction decoder decodes to obtain the control signal corresponding to the DSP instruction for controlling the operation of different modules or units. The DSP instruction includes the arithmetic instruction, the memory access instruction, the jump instruction and the no-operation instruction. If the DSP instruction is the arithmetic instruction or the memory access instruction, the first instruction decoder sends, to the arbitration module, the decoded control signal corresponding to the arithmetic instruction or the control signal corresponding to the memory access instruction 13; if the DSP instruction is the direct jump instruction or the no-operation instruction, sends the decoded control signal corresponding to the direct jump instruction or the control signal corresponding to the no-operation instruction to the first program counter above; and if the DSP instruction is the conditional jump instruction, executes the control signal corresponding to the conditional jump instruction when the conditional jump is met according to the jump condition parameter in the first general purpose register.

The first general purpose register above is configured for performing operation, memory access and control jump, and contains two 64-bit general purpose registers and one 1-bit general purpose register, wherein the 1-bit general purpose register REG_C stores the condition of the conditional jump. In addition, during operation, data may be loaded into the first general purpose register when executing the above-mentioned memory access instruction, so as to obtain relevant operation data from the first general purpose register when executing the arithmetic instruction subsequently, and an operation result may also be written back to the first general purpose register above. It can be understood that the memory access instruction completes data interaction between the first general purpose register and the data storage module 14 first. When the memory access instruction is executed, data is loaded from the data storage module 14 into the first general purpose register first, then an operation is performed by using the arithmetic logic unit 15 according to the arithmetic instruction, and an operation result is written back to the first general purpose register, and finally stored in the data storage module 14.

A first kernel module 12, configured for generating a corresponding control signal according to a DSP instruction code in a second read-only memory. The DSP instruction includes an arithmetic instruction, a memory access instruction, a jump instruction and a no-operation instruction.

In this embodiment, the second kernel module 12 may include: a second program counter, configured for generating a memory address corresponding to the DSP instruction; the second read-only memory connected with the second program counter, configured for storing the DSP instruction code, and determining the corresponding DSP instruction according to the memory address and sending the corresponding DSP instruction to a second instruction decoder; the second instruction decoder connected with the second read-only memory, configured for decoding the DSP instruction to obtain the corresponding control signal, and sending, to the arbitration module, the control signal corresponding to the arithmetic instruction and the control signal corresponding to the memory access instruction obtained by decoding; a second address mapping module connected with the second instruction decoder, configured for determining a physical address of a virtual address remapped to the data memory according to the control signal; and a second general purpose register connected with the second instruction decoder, configured for storing data information acquired from the data memory after the memory access instruction is executed and storing result information acquired from the arithmetic logic unit after the arithmetic instruction is executed; wherein the second program counter is further connected with the second instruction decoder and the second general purpose register respectively, and the second program counter is further configured for receiving a control signal corresponding to a direct jump instruction, a control signal corresponding to a no-operation instruction and a control signal corresponding to a conditional jump instruction sent by the second instruction decoder, and executing the control signal corresponding to the conditional jump instruction according to a jump condition parameter in the second general purpose register. It can be understood that, as shown in FIG. 4, similarly to the first kernel module 11, the second kernel module 12 independently contains one program counter, one read-only memory, one instruction decoder, one address mapping module and one general purpose register, and the working process among the above components is the same as that of the first kernel module 11, which will not be described in detail here. Further, in this embodiment, the DSP instruction involved in the second read-only memory of the second kernel module 12 may be different from the DSP instruction of the first kernel module 11, and may be modified according to operational tasks in the second kernel module 12. For example, a square root instruction in the arithmetic instruction may be deleted in the second kernel module 12, because a square root operation is rarely used, and a task involved in the square root may be completed by the first kernel module 11.

An arbitration module 13 respectively connected with the first kernel module 11 and the second kernel module 12, configured for receiving a control signal corresponding to the memory access instruction and/or the arithmetic instruction sent by the first kernel module 11 and the second kernel module 12, and screening out a control signal corresponding to a target memory access instruction and/or a target arithmetic instruction according to a preset priority.

In this embodiment, the arbitration module 13 includes a memory management unit arbitrator 131 and an arithmetic logic unit arbitrator 132, wherein the memory management unit arbitrator 131 is configured for receiving the control signal corresponding to the memory access instruction sent by the first kernel module 11 and the second kernel module 12, and screening out the control signal corresponding to the target memory access instruction according to the preset priority, and then sending the control signal corresponding to the target memory access instruction to the memory management unit 141; and the arithmetic logic unit arbitrator 132 is configured for receiving the control signal corresponding to the arithmetic instruction sent by the first kernel module 11 and the second kernel module 12, and screening out the control signal corresponding to the target arithmetic instruction according to the preset priority, and then sending the control signal corresponding to the target arithmetic instruction to the arithmetic logic unit 15.

It can be understood that by presetting priorities for the first kernel module 11 and the second kernel module 12, the memory management unit arbitrator 131 determines the control signal to be executed first from the simultaneously received control signals corresponding to the memory access instruction sent by the first kernel module 11 and the second kernel module 12 according to the priorities. The arithmetic logic unit arbitrator 132 determines the control signal to be executed first from the simultaneously received control signals corresponding to the arithmetic instruction sent by the first kernel module 11 and the second kernel module 12 according to the priorities.

In this embodiment, the memory management unit arbitrator 131 is further configured for, when receiving the control signals corresponding to the memory access instruction sent by the first kernel module 11 and the second kernel module 12 simultaneously, lowering a data valid signal of the second kernel module 12 to stop running the second program counter, and raising the data valid signal after the current memory access instruction is completely executed; and the arithmetic logic unit arbitrator 132 is further configured for, when receiving the control signals corresponding to the arithmetic instruction sent by the first kernel module 11 and the second kernel module 12 simultaneously, lowering the data valid signal of the second kernel module 12 to stop running the second program counter, and raising the data valid signal after the current arithmetic instruction is completely executed.

It can be understood that in this embodiment, the priority of the first kernel module 11 is set to be higher than the priority of the second kernel module 12. Therefore, when the first kernel module 11 and the second kernel module 12 send the control signals corresponding to the memory access instruction to the arbitration module 13 at the same time, the memory management unit arbitrator 131 is used to determine that the control signal corresponding to the memory access instruction sent by the first kernel module 11 has a higher priority and needs to be executed first. Therefore, the data valid signal (Instr valid) of the second kernel module 12 is lowered by the memory management unit arbitrator 131 to stop running the second program counter of the second kernel module 12 to generate a new pointer, and the data valid signal is raised after the execution of the current memory access instruction of the first kernel module 11 is completed. Similarly, when the first kernel module 11 and the second kernel module 12 send the control signals corresponding to the arithmetic instruction to the arbitration module 13 at the same time, the arithmetic logic unit arbitrator 132 is used to determine that the control signal corresponding to the arithmetic instruction sent by the first kernel module 11 has a higher priority and needs to be executed first. Therefore, the data valid signal (Instr valid) of the second kernel module 12 is lowered by the arithmetic logic unit arbitrator 132 to stop running the second program counter of the second kernel module 12 to generate a new pointer, and the data valid signal is raised after the current arithmetic instruction is executed.

A data storage module 14 connected with the arbitration module 13, configured for receiving and executing the control signal corresponding to the target memory access instruction sent by the arbitration module 13.

In this embodiment, the data storage module 14 may include: the data memory 142, configured for storing data information; and an MMU (Memory Management Unit) 141 connected with the arbitration module 13 and the data memory 142, configured for querying corresponding data information in the data memory 142 according to the physical addresses determined by the first address mapping module and the second address mapping module. It can be understood that the memory management unit 141 reads the corresponding data information in the data memory 142 according to the physical address determined by the first address mapping module or the second address mapping module, and feeds the data information back to the corresponding first general purpose register or the second general purpose register.

In this embodiment, the data memory 142 may include: a random access memory, configured for storing an intermediate variable, a preset parameter and a metering result; and a register block, configured for storing real time data corresponding to a target hardware device. It can be understood that the random access memory RAM is mainly used for storing the intermediate variable, parameters used in a metering algorithm, such as a calibration value, and a metering result, and occupies most space of the whole data memory 142. The register block is mainly configured for storing some data that needs to be processed by hardware in real time, such as real-time accumulated active power. In addition, there are also some registers with special functions.

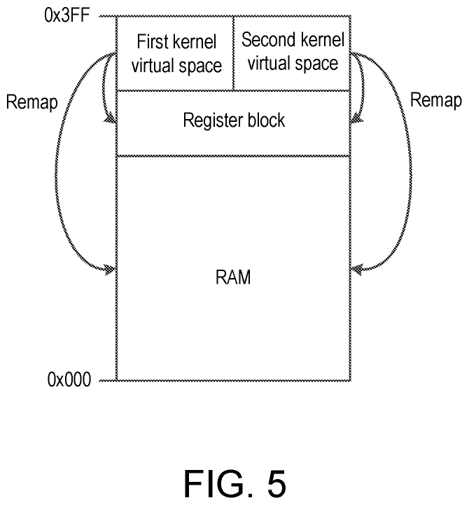

Moreover, for example, as shown in FIG. 5, the first address mapping module and the second address mapping module remap the virtual address to the random access memory or the register block respectively, so that the algorithm can be flexibly configured through the virtual address, and the same virtual address may be remapped to different physical addresses under different system configurations, thus realizing flexible configuration of data paths. This makes it possible to modify input and output signal addresses of the filter without additional DSP control codes, thus achieving a flexible and configurable effect. Meanwhile, the first kernel module and the second kernel module have their own independent address mapping module, which makes the two kernels share the same set of virtual address space, but realizes different mapping and saves limited addressing space.

Further, in this embodiment, the first kernel module 11 and the second kernel module 12 share the data storage module 14 and the arithmetic logic unit 15. However, to improve an access efficiency of the register block in the data storage module 14, it is also possible to adjust a shared access interface of the register block to two independent access interfaces, so that the first kernel module 11 and the second kernel module 12 can access the register block above at the same time. Furthermore, because the memory access instructions account for a large ratio in the DSP program, independent data storage modules can be built for the first kernel module 11 and the second kernel module 12, so that the two kernels can access the memory at the same time, which improves the operational ability of the DSP. In other words, the two kernels have their own data storage modules, but only share the arithmetic logic unit.

An arithmetic logic unit 15 connected with the arbitration module, configured for receiving and executing the control signal corresponding to the target arithmetic instruction sent by the arbitration module 13.

Further, to improve an execution efficiency of the arithmetic instructions of the first kernel module 11 and the second kernel module 12, independent access interfaces can be designed for each arithmetic unit in the arithmetic logic unit, so that the two kernels can execute different arithmetic instructions at the same time. For example, when the first kernel module 11 executes the addition in the arithmetic instruction, the second kernel module 12 can execute the subtraction in the arithmetic instruction, which reduces the possibility of conflict of the arithmetic instruction and improves the execution efficiency of the arithmetic instruction.

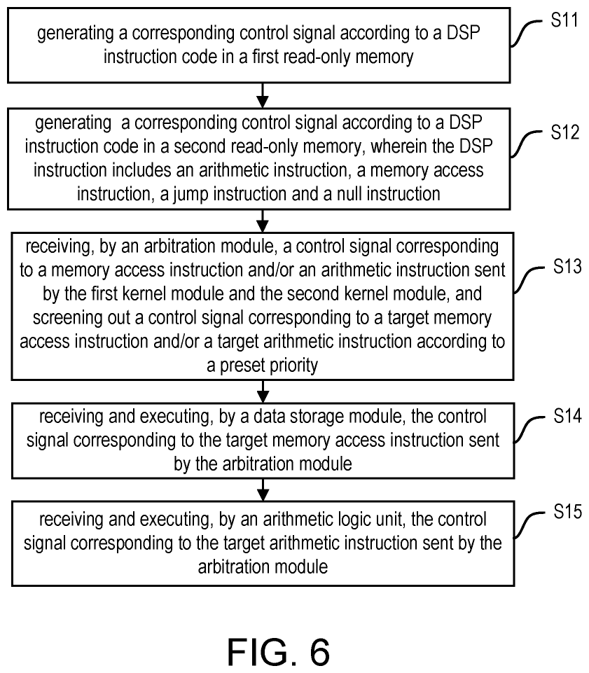

The embodiments of the present application disclose a digital signal process method for an electric energy metering chip. As shown in FIG. 6, the method includes the following steps of:

Step S11: generating, by a first kernel module, a corresponding control signal according to a DSP instruction code in a first read-only memory.

In this embodiment, the first kernel module mentioned above includes a first program counter, a first read-only memory, a first instruction decoder, a first address mapping module and a first general purpose register. In the specific operation process, the memory address (i.e., pointer) corresponding to the DSP instruction is generated by the first program counter and sent to the first read-only memory. The first read-only memory determines the corresponding DSP instruction according to the received memory address and sends the corresponding DSP instruction to the first instruction decoder. The first instruction decoder decodes to obtain the control signal. The DSP instruction includes but is not limited to the arithmetic instruction, the memory access instruction, the jump instruction and the no-operation instruction. If the DSP instruction is the arithmetic instruction or the memory access instruction, the first instruction decoder sends, to the arbitration module, the decoded control signal corresponding to the arithmetic instruction or the control signal corresponding to the memory access instruction; if the DSP instruction is the direct jump instruction or the no-operation instruction, sends the decoded control signal corresponding to the direct jump instruction or the control signal corresponding to the no-operation instruction to the first program counter above; and if the DSP instruction is the conditional jump instruction, executes the control signal corresponding to the conditional jump instruction when the conditional jump is met according to the jump condition parameter in the first general purpose register.

Step S12: generating, by a second kernel module, a corresponding control signal according to a DSP instruction code in a second read-only memory. The DSP instruction includes an arithmetic instruction, a memory access instruction, a jump instruction and a no-operation instruction.

In this embodiment, the second kernel module mentioned above includes a second program counter, a second read-only memory, a second instruction decoder, a second address mapping module and a second general purpose register. A specific working process in the second kernel module is the same as that in the first kernel module described above, and will not be described in detail here.

Step S13: receiving, by an arbitration module, a control signal corresponding to a memory access instruction and/or an arithmetic instruction sent by the first kernel module and the second kernel module, and screening out a control signal corresponding to a target memory access instruction and/or a target arithmetic instruction according to a preset priority.

In this embodiment, the arbitration module, after receiving the control signal corresponding to the memory access instruction and/or the arithmetic instruction sent by the first kernel module and the second kernel module, may screen out the control signal corresponding to the target memory access instruction and/or the target arithmetic instruction according to the preset priority. The above priority is a preset priority for the kernel modules. It can be understood that by setting the priorities for the kernel modules, the kernel module with a higher priority can run continuously, so that the user can hand over important tasks to the kernel module with a higher priority and hand over the remaining tasks to the kernel module with a lower priority.

In this embodiment, the arbitration module includes a memory management unit arbitrator and an arithmetic logic unit arbitrator. When the memory management unit arbitrator receives the control signals corresponding to the memory access instruction sent by the first kernel module and the second kernel module simultaneously, the data valid signal of the second kernel module is lowered to stop running the second program counter, and the data valid signal is raised after the current memory access instruction is completely executed. Similarly, when the arithmetic logic unit arbitrator receives the control signals corresponding to the arithmetic instruction sent by the first kernel module and the second kernel module simultaneously, the data valid signal of the second kernel module is lowered to stop running the second program counter, and the data valid signal is raised after the current arithmetic instruction is completely executed.

Step S14: receiving and executing, by a data storage module, the control signal corresponding to the target memory access instruction sent by the arbitration module.

In this embodiment, the data storage module, after receiving the control signal corresponding to the target memory access instruction sent by the arbitration module, responds to the control signal to feed back corresponding data information.

Step S15: receiving and executing, by an arithmetic logic unit, the control signal corresponding to the target arithmetic instruction sent by the arbitration module.

In this embodiment, the arithmetic logic unit, after receiving the control signal corresponding to the target arithmetic instruction sent by the arbitration module, performs logical operation according to the control signal and feeds back a corresponding operation result.

It can be seen that in this application, the corresponding control signal is generated by the first kernel module according to the DSP instruction code in the first read-only memory, and the corresponding control signal is generated by the second kernel module according to the DSP instruction code in the second read-only memory, wherein the DSP instruction includes the arithmetic instruction, the memory access instruction, the jump instruction and the no-operation instruction; then the arbitration module respectively connected with the first kernel module and the second kernel module is used to receive the control signal corresponding to the memory access instruction and/or the arithmetic instruction sent by the first kernel module and the second kernel module, and screen out the control signal corresponding to the target memory access instruction and/or the target arithmetic instruction according to the preset priority; and then, the control signal corresponding to the target memory access instruction is received and executed by the data storage module, and the control signal corresponding to the target arithmetic instruction is received and executed by the arithmetic logic unit. It can be seen that the operational ability of the DSP is improved by newly adding one kernel. Meanwhile, the product cost is reduced since the first kernel module and the second kernel module share the data storage module and the arithmetic logic unit, and the running power consumption is reduced without increasing the clock frequency of the system.

The various embodiments in this specification are described in a progressive manner. Each embodiment focuses on the differences from the other embodiments, and the same or similar parts between the various embodiments may be referred to each other. As for the device embodiments, since it is basically similar to the method embodiments, the description of the device embodiments is relatively simple. For relevant points, please refer to the partial description of the method embodiments.

Finally, it should be also noted that relational terms herein such as first and second, etc., are used merely to distinguish one entity or operation from another entity or operation, and do not necessarily require or imply there is any such relationship or order between these entities or operations. Furthermore, the terms “including”, “comprising” or any variations thereof are intended to embrace a non-exclusive inclusion, such that a process, a method, an article, or a device including a series of elements, includes not only those elements but also includes other elements not expressly listed, or also includes elements inherent to such process, method, article, or device. In the absence of further limitation, an element defined by the phrase “including a . . . ” does not exclude the existence of additional identical elements in the process, the method, the article, or the device.

The digital signal process device and method for the electric energy metering chip provided by the present invention are described in detail above. Specific examples are applied to explain the principle and implementation of the present invention herein. The above embodiments are only used to help understand the method of the present invention and the core idea thereof. Meanwhile, for those of ordinary skills in the art, there will be changes in the specific implementation and application scope according to the idea of the present invention. To sum up, the contents of this specification should not be construed as limiting the present invention.

What is claimed is:

1. A digital signal process device for an electric energy metering chip, comprising:
a first kernel module, configured for generating a corresponding control signal according to a DSP instruction code in a first read-only memory;
a second kernel module, configured for generating a corresponding control signal according to a DSP instruction code in a second read-only memory; wherein a DSP instruction comprises an arithmetic instruction, a memory access instruction, a jump instruction and a no-operation instruction;
an arbitration module, respectively connected with the first kernel module and the second kernel module, configured for receiving the control signal corresponding to the memory access instruction and/or the arithmetic instruction sent by the first kernel module and the second kernel module, and screening out the control signal corresponding to a target memory access instruction and/or a target arithmetic instruction according to a preset priority;
a data storage module, connected with the arbitration module, configured for receiving and executing the control signal corresponding to the target memory access instruction sent by the arbitration module; and
an arithmetic logic unit, connected with the arbitration module, configured for receiving and executing the control signal corresponding to the target arithmetic instruction sent by the arbitration module.

2. The digital signal process device for the electric energy metering chip according to claim 1, wherein the first kernel module comprises:
a first program counter, configured for generating a memory address corresponding to the DSP instruction;
the first read-only memory, connected with the first program counter, configured for storing the DSP instruction code, and determining a corresponding DSP instruction according to the memory address and sending the corresponding DSP instruction to a first instruction decoder;
the first instruction decoder, connected with the first read-only memory, configured for decoding the DSP instruction to obtain a corresponding control signal, and sending, to the arbitration module, the control signal corresponding to the arithmetic instruction and the control signal corresponding to the memory access instruction obtained by decoding;
a first address mapping module, connected with the first instruction decoder, configured for determining a physical address of a virtual address remapped to a data memory according to the control signal; and
a first general purpose register, connected with the first instruction decoder, configured for storing data information acquired from the data memory after the memory access instruction is executed and storing result information acquired from the arithmetic logic unit after the arithmetic instruction is executed;
wherein the first program counter is further connected with the first instruction decoder and the first general purpose register, respectively, and the first program counter is further configured for receiving a control signal corresponding to a direct jump instruction, a control signal corresponding to a no-operation instruction and a control signal corresponding to a conditional jump instruction sent by the first instruction decoder, and executing the control signal corresponding to the conditional jump instruction according to a jump condition parameter in the first general purpose register.

3. The digital signal process device for the electric energy metering chip according to claim 1, wherein the second kernel module comprises:
a second program counter, configured for generating a memory address corresponding to the DSP instruction;
the second read-only memory, connected with the second program counter, configured for storing the DSP instruction code, and determining a corresponding DSP instruction according to the memory address and sending the corresponding DSP instruction to a second instruction decoder;
the second instruction decoder, connected with the second read-only memory, configured for decoding the DSP instruction to obtain a corresponding control signal, and sending, to the arbitration module, the control signal corresponding to the arithmetic instruction and the control signal corresponding to the memory access instruction obtained by decoding;
a second address mapping module, connected with the second instruction decoder, configured for determining a physical address of a virtual address remapped to a data memory according to the control signal; and
a second general purpose register, connected with the second instruction decoder, configured for storing data information acquired from the data memory after the memory access instruction is executed and storing result information acquired from the arithmetic logic unit after the arithmetic instruction is executed;
wherein the second program counter is further connected with the second instruction decoder and the second general purpose register respectively, and the second program counter is further configured for receiving a control signal corresponding to a direct jump instruction, a control signal corresponding to a no-operation instruction and a control signal corresponding to a conditional jump instruction sent by the second instruction decoder, and executing the control signal corresponding to the conditional jump instruction according to a jump condition parameter in the second general purpose register.

4. The digital signal process device for the electric energy metering chip according to claim 2, wherein the data storage module comprises:
the data memory, configured for storing the data information; and
a memory management unit, connected with the arbitration module and the data memory, configured for querying corresponding data information in the data memory according to the physical addresses determined by the first address mapping module.

5. The digital signal process device for the electric energy metering chip according to claim 4, wherein the data memory comprises:
a random access memory, configured for storing an intermediate variable, a preset parameter and a metering result; and
a register block, configured for storing real time data corresponding to a target hardware device.

6. The digital signal process device for the electric energy metering chip according to claim 1, wherein the arbitration module comprises a memory management unit arbitrator and an arithmetic logic unit arbitrator, wherein:
the memory management unit arbitrator is configured for receiving the control signal corresponding to the memory access instruction sent by the first kernel module and the second kernel module, and screening out the control signal corresponding to the target memory access instruction according to the preset priority, and then sending the control signal corresponding to the target memory access instruction to the memory management unit; and
the arithmetic logic unit arbitrator is configured for receiving the control signal corresponding to the arithmetic instruction sent by the first kernel module and the second kernel module, and screening out the control signal corresponding to the target arithmetic instruction according to the preset priority, and then sending the control signal corresponding to the target arithmetic instruction to the arithmetic logic unit.

7. The digital signal process device for the electric energy metering chip according to claim 6, wherein the memory management unit arbitrator is further configured for, when receiving the control signals corresponding to the memory access instruction sent by the first kernel module and the second kernel module simultaneously, lowering a data valid signal of the second kernel module to stop running the second program counter, and raising the data valid signal after a current memory access instruction is completely executed; and
the arithmetic logic unit arbitrator is further configured for, when receiving the control signals corresponding to the arithmetic instruction sent by the first kernel module and the second kernel module simultaneously, lowering the data valid signal of the second kernel module to stop running the second program counter, and raising the data valid signal after a current arithmetic instruction is completely executed.

8. A digital signal process method for an electric energy metering chip, comprising:
generating a corresponding control signal according to a DSP instruction code in a first read-only memory;
generating a corresponding control signal according to a DSP instruction code in a second read-only memory; wherein a DSP instruction comprises an arithmetic instruction, a memory access instruction, a jump instruction and a no-operation instruction;
receiving, by an arbitration module, a control signal corresponding to a memory access instruction and/or an arithmetic instruction sent by the first kernel module and the second kernel module, and screening out a control signal corresponding to a target memory access instruction and/or a target arithmetic instruction according to a preset priority;
receiving and executing, by a data storage module, the control signal corresponding to the target memory access instruction sent by the arbitration module; and
receiving and executing, by an arithmetic logic unit, the control signal corresponding to the target arithmetic instruction sent by the arbitration module.

9. The digital signal process device for the electric energy metering chip according to claim 3, wherein the data storage module comprises:
the data memory, configured for storing the data information; and
a memory management unit, connected with the arbitration module and the data memory, configured for querying corresponding data information in the data memory according to the physical addresses determined by the second address mapping module.
